(19) United States
(12) Patent Application Publication
(10) Pub. No.: US 2015/0262959 A1
(43) Pub. Date: Sep. 17, 2015

(54) SEMICONDUCTOR DEVICE AND METHOD OF MANUFACTURING THE SAME

(71) Applicant: KABUSHIKI KAISHA TOSHIBA, Tokyo (JP)

(72) Inventors: Yuuji HISAZATO, Fuchu Tokyo (JP); Kazuya KODANI, Kawasaki Kanagawa (JP); Yo SASAKI, Saitama Saitama (JP); Daisuke HIRATSUKA, Yokohama Kanagawa (JP); Hitoshi MATSUMURA, Yokohama Kanagawa (JP); Hideaki KITAZAWA, Kamakura Kanagawa (JP); Nobumitsu TADA, Hachiouji Tokyo (JP); Hiroki SEKIYA, Kawasaki Kanagawa (JP)

(21) Appl. No.: 14/475,535

(22) Filed: Sep. 2, 2014

(30) Foreign Application Priority Data
Mar. 12, 2014 (JP) 2014-049069

(51) Int. Cl. H01L 23/00

(52) U.S. Cl. CPC H01L 24/33; H01L 24/27; H01L 24/83; H01L 2224/27334; H01L 2224/291; H01L 2224/3005; H01L 2924/014; H01L 2924/37002; H01L 2924/0105; H01L 2924/01027; H01L 2924/01051; H01L 2924/05432; H01L 2224/83801

(57) ABSTRACT

A semiconductor device includes a substrate joined to a base by a first junction material and a semiconductor element joined to the substrate by a second junction material. At least one of the first and second junction materials comprises tin, antimony, and cobalt. In some embodiments, the junction materials comprise cobalt having a weight percentage between 0.05 wt % and 0.2 wt %, antimony with a weight percentage between 1 wt % and 10 wt %, and the balance being substantially tin.

### CROSS-REFERENCE TO RELATED APPLICATION

This application is based upon and claims the benefit of priority from Japanese Patent Application No. 2014-049069, filed Mar. 12, 2014, the entire contents of which are incorporated herein by reference.

### FIELD

Embodiments described herein relate generally to a semiconductor device and a method of manufacturing the same.

### BACKGROUND

Semiconductor devices for controlling power are widely used in industrial fields such as automobiles, trains, and home electronics. These semiconductor devices include a semiconductor element such as a MOS transistor and have a structure in which this semiconductor element is mounted on a heat radiating base through a metal terminal. In order to stably operate such a semiconductor device, it is necessary that junction portions between the respective components included in the semiconductor device withstand repeated cooling-heating cycles and a power cycling over a long period of time. There is room for improvement in joining materials such as a solder used for these junction portions to increase semiconductor device lifetime and performance.

### DESCRIPTION OF THE DRAWINGS

FIG. 1 is a cross-sectional view schematically illustrating a semiconductor device according to exemplary first embodiment.

FIG. 2 is a photograph illustrating an external appearance of a sample from a joining test.

FIG. 3 is a cross-sectional view schematically illustrating the sample from a joining test.

FIG. 4 depicts ultrasonic flaw detection images before and after a joining test in which a SnSbCo material is used.

FIG. 5 depicts ultrasonic flaw detection images before and after a joining test in which a SnSb material is used.

FIGS. 6A and 6B depict ultrasonic flaw detection images before and after a joining test in which a SnAgCu material is used.

FIG. 7 depicts ultrasonic flaw detection images before and after a joining test according to a comparative example.

FIG. 8 is a graph illustrating a relationship between the number of solder sheets and a peeling ratio in a junction portion in which the SnSbCo material is used.

FIG. 9 is cross-sectional images of junction portions in which the SnSbCo material is used.

FIG. 10 is a graph illustrating a relationship between the number of solder sheets and a peeling ratio in a junction portion in which the SnSb material is used.

FIG. 11 is cross-sectional images of junction portions in which the SnSb material is used.

FIG. 12 is a graph illustrating a relationship between a crack length and the thickness of the junction portion in which the SnSb material is used.

FIG. 13 is a graph illustrating a relationship between a crack length and the thickness of the junction portion in which the SnSbCo material is used.

FIG. 14 is a cross-sectional scanning electron microscope (SEM) image illustrating the junction portion in which the SnSb material is used.

FIG. 15 is an X-ray image illustrating the junction portion in which the SnSb material is used.

FIGS. 16A and 16B are diagrams illustrating a grain size distribution of the junction portion in which the SnSb material is used.

FIG. 17 is a cross-sectional SEM image illustrating the junction portion in which the SnSbCo material is used.

FIG. 18 is an X-ray image illustrating the junction portion in which the SnSbCo material is used.

FIGS. 19A and 19B are diagrams illustrating a grain size distribution of the junction portion in which the SnSbCo material is used.

### DETAILED DESCRIPTION

Embodiments include a semiconductor device having a junction portion with improved thermal fatigue resistance and a method of manufacturing the same.

In an embodiment, a semiconductor device includes a substrate joined to a base (base plate) via a first junction material and a semiconductor element joined to the substrate via a second junction material. At least one of the first junction material and the second junction material comprises tin, antimony, and cobalt. In some embodiments, at least one of the first and second junction materials comprises cobalt having a weight percentage between 0.05 wt % and 0.2 wt % (inclusive), antimony with a weight percentage between 1 wt % and 10 wt % (inclusive), and the balance being substantially tin. The junction materials may on occasion be referred to as a “solder” or “solder material.”

In general, according to one embodiment, there is provided a semiconductor device including: a base portion; a substrate that is provided on the base portion; and a semiconductor element that is provided on the substrate. The semiconductor device further includes a junction portion that is disposed between at least one of the base portion and the substrate and the substrate and the semiconductor element, the junction portion comprises tin, antimony, and cobalt.

Hereinafter, the exemplary embodiments will be described with reference to the accompanying drawings. In the drawings, the same or substantially similar components/elements are represented by the same reference numerals, the detailed descriptions of repeated components/elements will not be repeated, and description of differences will be the focus. The drawings are conceptual and schematic. For example, a relationship between the thickness and the width of each component and ratios of the sizes of the respective components are not necessarily the same as those of the actual ones. In addition, when the same component is illustrated, the dimension and the ratio thereof may vary depending on the drawings.

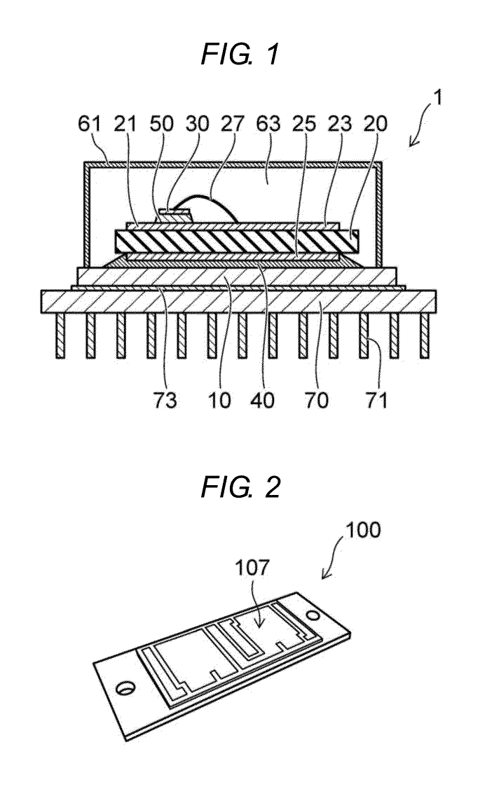

FIG. 1 is a cross-sectional view schematically illustrating a semiconductor device 1 according to a first embodiment. The semiconductor device 1 is a power semiconductor device for controlling power.

The semiconductor device 1 includes a base portion 10, a substrate 20 that is provided on the base portion 10, and a semiconductor element 30 that is provided on the substrate 20. The semiconductor element 30 is a power semiconductor element such as a power MOS transistor.

The semiconductor device 1 includes a first junction portion 40 that is provided between the base portion 10 and the substrate 20 and a second junction portion 50 that is provided between the substrate 20 and the semiconductor element 30. At least one of the first junction portion 40 and the second junction portion 50 contains tin (Sn), antimony (Sb), and cobalt (Co). “Containing tin, antimony, and cobalt” in this context means that the three elements are included as major compositional elements and that, any other elements are included in the composition of the junction portion are not intentionally added and the content thereof is at a level of unavoidable impurities which cannot be economically removed or excluded from the junction portion.

For example, during the operation of the semiconductor device 1, the semiconductor element 30 is supplied with power and consequently generates heat. This heat is dissipated through the substrate 20 and the base portion 10. In this process, the heat from the semiconductor element 30 is conducted to the first junction portion 40 and the second junction portion 50. The first junction portion 40 and the second junction portion 50 may deteriorate due to a long-term operation of the semiconductor device 1.

For example, a stress by a cooling-heating cycle generated by switching on and off the semiconductor element 30 or a stress by a power cycle generated by power fluctuation is applied to the first junction portion 40. As a result, a crack can be formed in or at the first junction portion 40, and the crack is propagated by repetition of a cooling-heating cycle, a power cycle, or the like, which may lead to junction fracture.

In this exemplary embodiment, a junction material including tin, antimony, and cobalt is used for at least one of the first junction portion 40 and the second junction portion 50. Accordingly, the thermal fatigue resistance of the junction portion is improved. For example, the propagation of a crack may be suppressed, and the junction fracture may be avoided. As a result, the reliability of the semiconductor device 1 may be improved.

Next, the semiconductor device 1 will be described in detail with reference to FIG. 1.

As illustrated in FIG. 1, the substrate 20 includes a metal film 25 on a lower surface thereof on the base portion 10 side and includes power terminals 21 and 23 on an upper surface thereof that is opposite to the base portion 10 side. The metal film 25 and the power terminals 21 and 23 are, for example, copper (Cu) films.

For example, the semiconductor element 30 is mounted on the power terminal 21 through the second junction portion 50. In addition, the semiconductor element 30 is electrically connected to the power terminal 23 through, for example, an aluminum wire 27. It is preferable that the second junction portion 50 be a material having a melting point higher than that of the first junction portion 40. In addition, the first junction portion 40 may be, for example, a diffused junction in which a joining material such as tin is used.

The substrate 20 on which the semiconductor element 30 is disposed is fixed on the base portion 10 through the first junction portion 40. A metal or a heat radiating ceramic such as alumina is used for the base portion 10. A material (hereinafter, referred to as “SnSbCo material”) containing tin, antimony, and cobalt is used for the first junction portion 40. As a result, the thermal fatigue resistance of the first junction portion 40 may be improved.

The content of cobalt in the first junction portion 40 is, for example, 0.05 wt % to 0.2 wt % (inclusive). When the content of cobalt is less than 0.05 wt %, substantially the same characteristics as those of a SnSb material not containing cobalt are exhibited. That is, any effect due to inclusion of cobalt is not appreciable. On the other hand, when the content of cobalt is greater than 0.2 wt %, wettability as a solder deteriorates, and a void or the like may be formed on a junction surface. Therefore, the content of cobalt is preferably from 0.05 wt % to 0.2 wt %.

In addition, the content of antimony in the first junction portion 40 is, for example, 1 wt % to 10 wt % (inclusive). When the content of antimony is less than 1 wt %, any effect due to inclusion of antimony is not appreciable. On the other hand, when the content of antimony is greater than 10 wt %, the hardness is increased, and the junction may be brittle.

In addition, when the base portion 10 and the substrate 20 are joined to each other, it is preferable that the first junction portion 40 be held at a temperature higher than a melting point (of the material of junction portion 40) for at least one minute. As a result, cobalt is diffused in the first junction portion 40 to a portion contacting with the base portion 10 and the first junction portion 40 of the substrate 20. For example, a structure of a contact portion, where cobalt is solid-solubilized, between the first junction portion and the metal film 25 or the base portion 10 is obtained. As a result, the thermal fatigue resistance of the first junction portion 40 may be further improved.

A case 61 that covers the substrate 20 and the semiconductor element 30 is disposed on the base portion 10. The inside of the case 61 is filled with a resin to protect the semiconductor element 30. The power terminals 21 and 23 are drawn out from the case 61 to the outside such that the semiconductor element 30 may be connected to an external circuit.

In addition, in another example embodiment, an epoxy resin may be molded on the base portion 10 to seal the semiconductor element 30 and the substrate 20. A portion of the power terminals 21 and 23 are drawn out from the molded epoxy resin to function as terminals to be connected to an external circuit.

Further, the semiconductor device 1 is installed on, for example, a heat sink 70. The semiconductor device 1 is fixed on the heat sink 70 through, for example, a heat radiating grease (paste) 73. Heat from the semiconductor element 30 is conducted to the heat sink 70 through the base portion 10 and is dissipated to the outside through a heat radiating fin 71 provided in the heat sink 70.

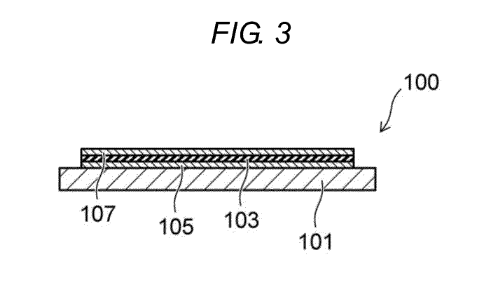

Hereinafter, characteristics of a junction portion in which the SnSbCo material is used will be described with reference to FIGS. 2 to 19.

FIG. 2 is an image illustrating an external appearance of a sample 100 from a joining test.

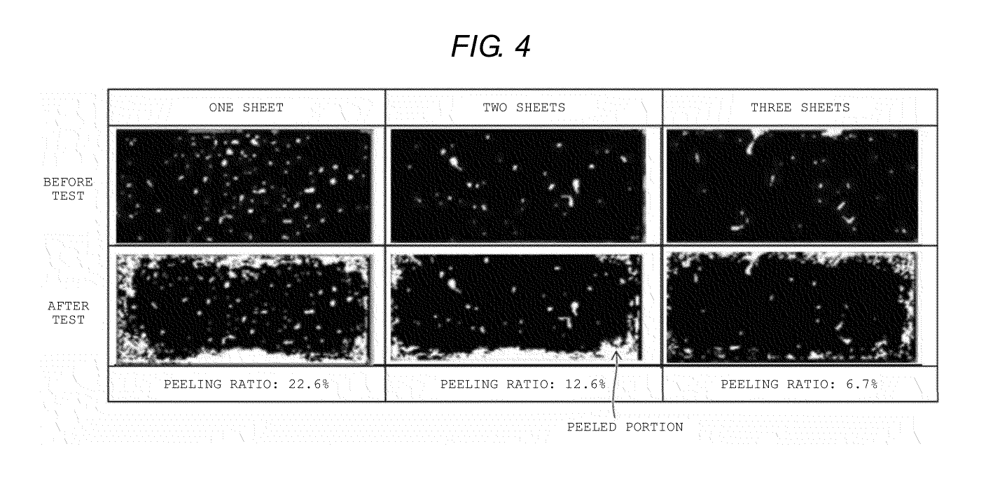

FIG. 3 is a cross-sectional view schematically illustrating the sample 100 from a joining test.

As illustrated in FIG. 2, the sample 100 includes a rectangular base portion 101, and a metal pattern 107 is provided on an upper surface of the base portion 101.

As illustrated in FIG. 3, the sample 100 has a structure in which a ceramic plate 103 is joined onto the base portion 101. The metal pattern 107 is provided on an upper surface of the ceramic plate 103. A junction portion 105 is provided between the ceramic plate 103 and the base portion 101. The base portion 101 and the metal pattern 107 are formed of, for example, copper (Cu).

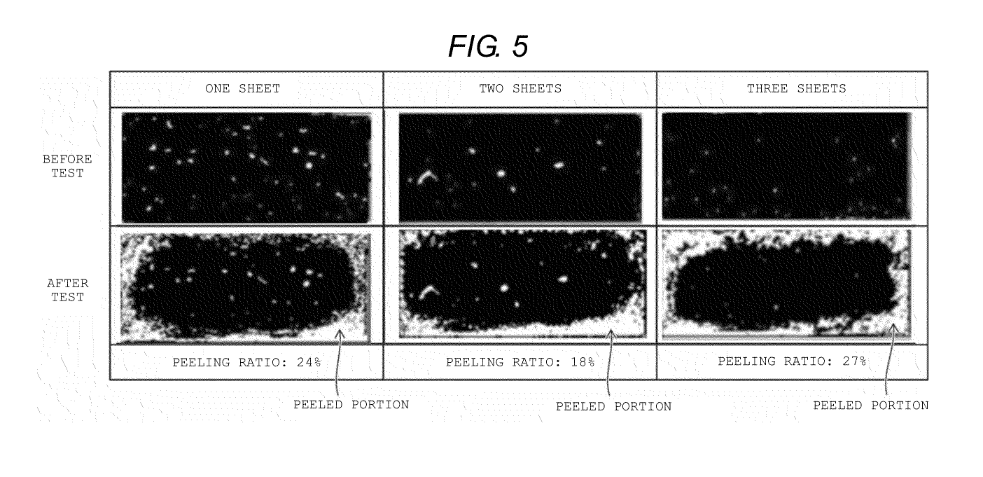

FIGS. 4 to 7 depict ultrasonic flaw detection images illustrating the results of a thermal fatigue test which was carried out using the sample 100.

In an example of FIG. 4, a solder material used in the junction portion 105, the content of antimony (Sb) is 5 wt %, and the content of cobalt (Co) is 0.1 wt %. The balance includes tin (Sn). The junction portion 105 containing the SnSbCo material with this composition was subjected to a thermal shock test in which a heating cycle of −40° C. to 170° C. was repeated 300 times. The time period of one cycle was 30 minutes.

FIG. 4 illustrates the results of measuring a state of the junction portion 105 using an ultrasonic flaw detection method before and after the thermal shock test. The upper image portion illustrates the junction portion 105 before the thermal shock test, and the lower image portion illustrates the junction portion 105 after the thermal shock test. The junction portions 105 of the respective samples used in the test contain one to three solder sheets, respectively. In addition, a peeled area of each sample after the thermal shock test was measured using the ultrasonic flaw detection method, and a peeling ratio thereof is calculated.

As illustrated in the upper portion of FIG. 4, peeling is not observed on the junction portion 105 before the thermal shock test. On the other hand, after the thermal shock test, about 22.6% of a junction surface in the junction portion 105 formed using one solder sheet is peeled off. As the number of solder sheets is increased, the peeling ratio is decreased. In the junction portion 105 in which three solder sheets are used, the peeling ratio is about 6.7%.

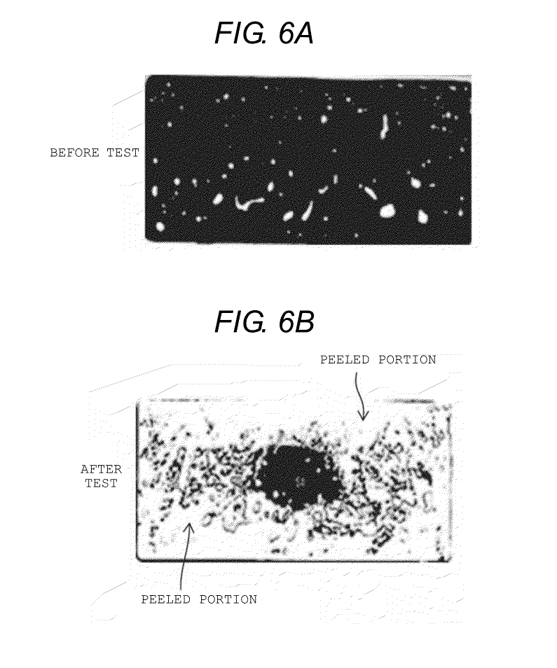

FIG. 5 depicts ultrasonic flaw detection images illustrating characteristics of a junction portion in which the SnSb material containing 5 wt % of antimony (Sb) is used. The upper image portion illustrates the junction portion before the thermal shock test, and the lower image portion illustrates the junction portion after the thermal shock test.

As illustrated in the upper image portion of FIG. 5, when the SnSb material is used, peeling is also not observed in the junction portion 105 before the thermal shock test. On the other hand, after the thermal shock test, about 24% of a junction surface in the junction portion 105 formed using one solder sheet is peeled off. In addition, when two solder sheets are used, about 18% of a junction surface is peeled off, and when three solder sheets are used, about 27% of a junction surface is peeled off. In this example, a correlation between the number of solder sheets and the peeling ratio is not found, but it may be seen that the peeling ratio of this example is greater than that of the junction portion 105 containing the SnSbCo material.

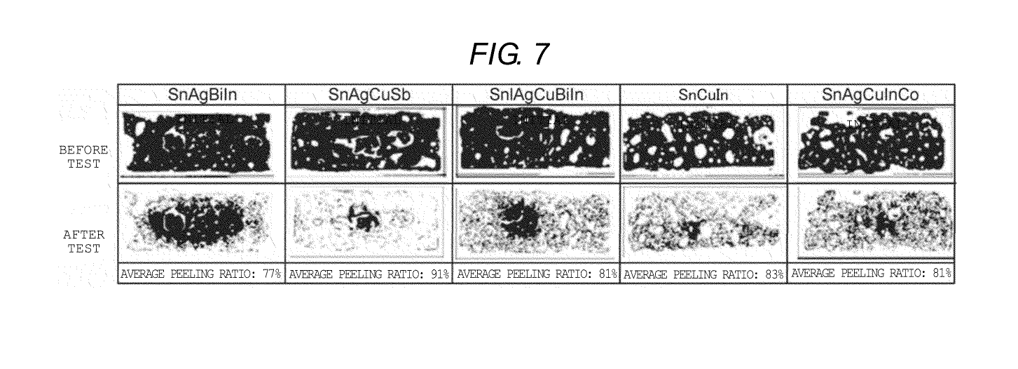

FIGS. 6A and 6B are ultrasonic flaw detection images illustrating characteristics of a junction portion in which a SnAgCu material is used. FIG. 6A illustrates the junction portion before the thermal shock test, and FIG. 6B illustrates the junction portion after the thermal shock test. Even in this case, peeling is not observed in the junction portion before the thermal shock test. On the other hand, after the thermal shock test, it may be seen that about 90% of a junction surface of the junction portion is peeled off.

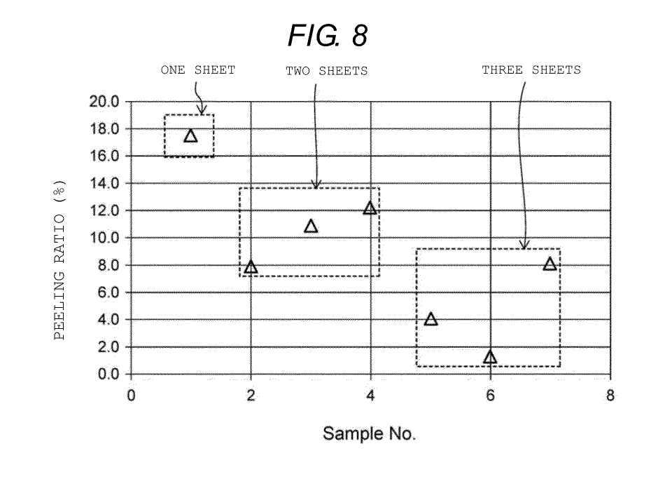

FIG. 7 depicts ultrasonic flaw detection images illustrating characteristics of a junction portion according to a comparative example. As a material of the junction portion, five types of solder materials are used, the solder materials including SnAgBiIn (Ag: 3 wt %, Bi: 3 wt %), SnAgCuSb (Cu: 3 wt %), SnAgCuBiIn (Cu: 1.6 wt %, Bi: 0.2 wt %), SnCuIn (Cu: 3 wt %), and SnAgCuInCo (Cu: 3 wt %). The upper image portion illustrates the junction portion before the thermal shock test, and the lower image portion illustrates the junction portion after the thermal shock test.

When the five types of solder materials described herein are used, as illustrated in the upper image portion of FIG. 7, a peeled portion is observed in the junction portion before the thermal shock test. That is, it is considered that the wettability as a solder is poorer than that of the SnSb material and the SnAgCu material.

Furthermore, as illustrated in the lower image portion of FIG. 7, the peeling ratios of the SnAgBiIn material, the SnAgCuSb material, the SnAgCuBiIn material, the SnCuIn material, the SnCuIn material, and the SnAgCuInCo material after the thermal shock test are about 77%, 91%, 81%, 83%, and 81%, respectively.

As such, it may be seen that the peeling ratio of the junction surface after the thermal shock test in the comparative example is greater than that of the SnSbCo material and the SnSb material. That is, it may be said that the thermal fatigue resistance of solder materials in which Ag, Cu, In, and the like are added to tin (Sn) is poorer than that of the SnSbCo material and the SnSb material. For example, when a thermal stress is repeatedly applied to these comparative solder materials, Ag or Cu is segregated on a grain boundary portion of recrystallized tin (Sn), and an intermetallic compound is formed. Therefore, it is considered that the grain boundary portion is embrittled and a crack is likely to be formed. The formed crack is likely to be propagated by a heating cycle, which may cause a failure and reduction in lifetime.

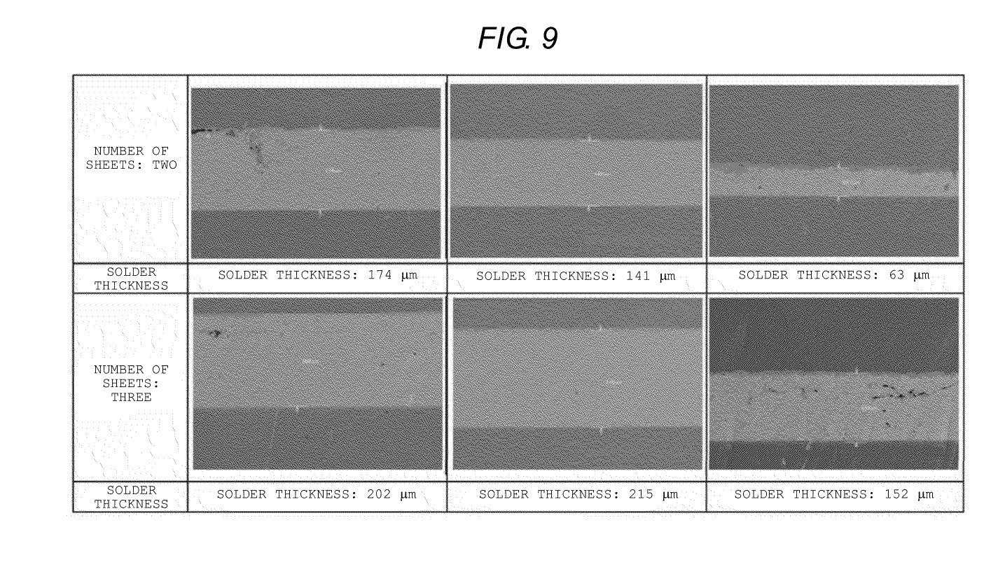

FIG. 8 is a graph illustrating a relationship between the number of solder sheets and a peeling ratio in the junction portion 105 in which the SnSbCo material (Sb: 5 wt %, Co: 0.1 wt %) is used. The horizontal axis represents Sample No., and the vertical axis represents the peeling ratio (area ratio: %). Samples having the same number of solder sheets are grouped. As illustrated in FIG. 8, as the number of solder sheets is increased, the peeling ratio of the junction portion 105 is decreased.

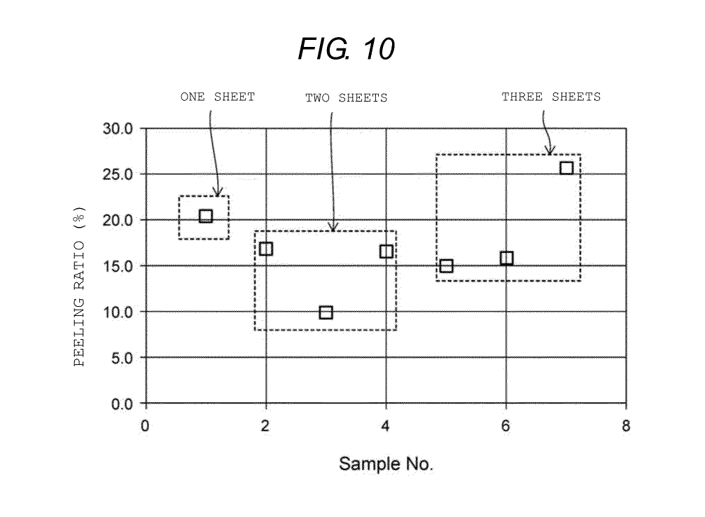

FIG. 9 is cross-sectional images of junction portions in which the SnSbCo material is used. The upper image portion illustrates a cross-section of the junction portion 105 in which two solder sheets are used, and the lower image portion illustrates a cross-section of the junction portion 105 in which three solder sheets are used. For each cross-section, three images are illustrated. The center image portion illustrates a cross-section at the center of the junction portion 105, and the images on both sides illustrate cross-sections of both ends between which the center is interposed.

In this example, it may be seen that the inclination of the junction portion 105 in which two solder sheets are used is greater than that of the junction portion 105 in which three solder sheets are used. On the other hand, as illustrated in FIG. 8, as the number of solder sheets is increased, the peeling ratio of the junction portion 105 is decreased.

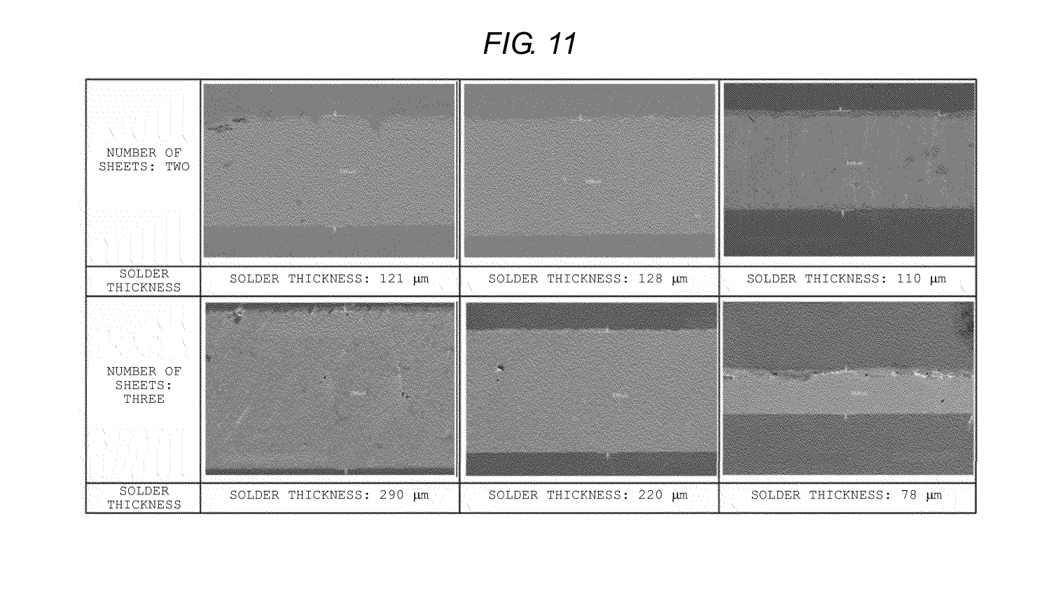

FIG. 10 is a graph illustrating a relationship between the number of solder sheets and a peeling ratio in the junction portion 105 in which the SnSb material (Sb: 5 wt %) is used. The horizontal axis represents Sample No., and the vertical axis represents the peeling ratio (area ratio: %). Samples having the same number of solder sheets are grouped.

In FIG. 10, the peeling ratio of the junction portion 105 does not depend on the number of solder sheets. The peeling ratio of the junction portion 105 in which two solder sheets are used is small, and the peeling ratio of the junction portion 105 in which three solder sheets are used tends to be greater than that of the junction portion 105 in which two solder sheets are used.

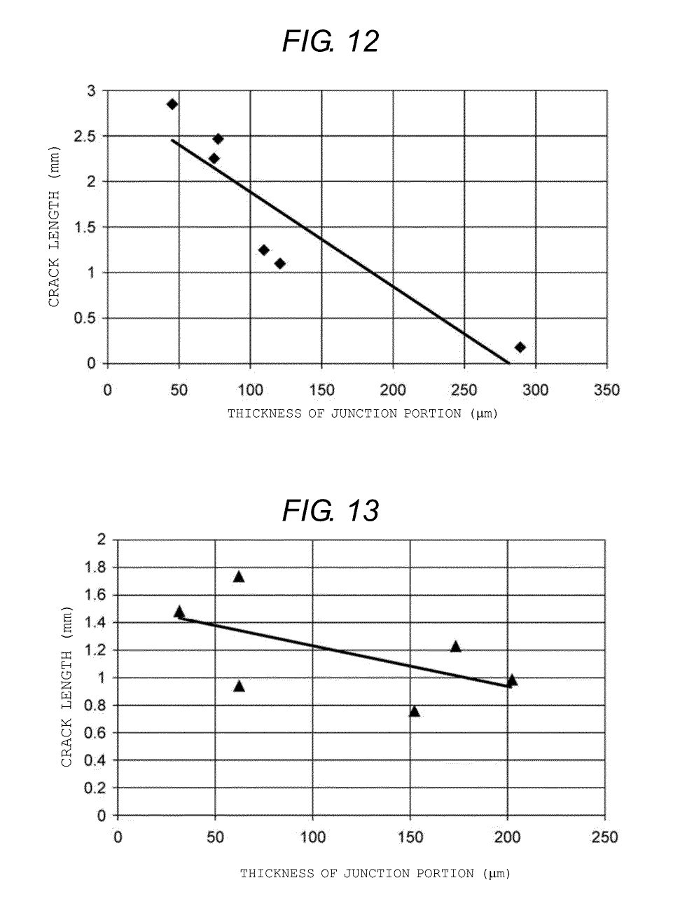

FIG. 11 is cross-sectional images of the junction portions 105 in which the SnSb material is used. The upper image portion illustrates a cross-section of the junction portion 105 in which two solder sheets are used, and the lower image portion illustrates a cross-section of the junction portion 105 in which three solder sheets are used. For each cross-section, three images are illustrated. The center image illustrates a cross-section at the center of the junction portion 105, and the images on both sides illustrate cross-sections of both ends between which the center is interposed.

In this example, it may be seen that the inclination of the junction portion 105 in which three solder sheets are used is greater than that of the junction portion 105 in which two solder sheets are used. On the other hand, the peeling ratio of the junction portion 105 in which three solder sheets are used tends to be greater than that of the junction portion 105 in which two solder sheets are used. In addition, the peeling ratio of the SnSb material is greater than that of the SnSbCo material.

In the examples illustrated in FIGS. 8 to 11, it may be seen that the peeling ratio of the junction portion 105 may be suppressed by adding cobalt to the SnSb material. In addition, it is presumed that the thickness distribution of the junction portion 105 does not affect the peeling ratio.

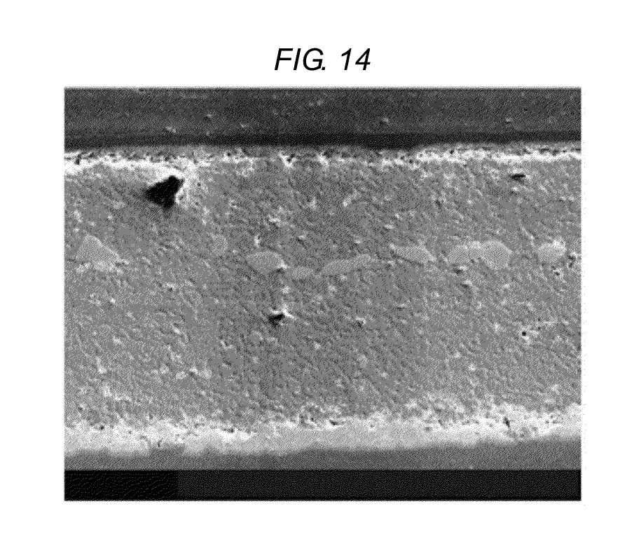

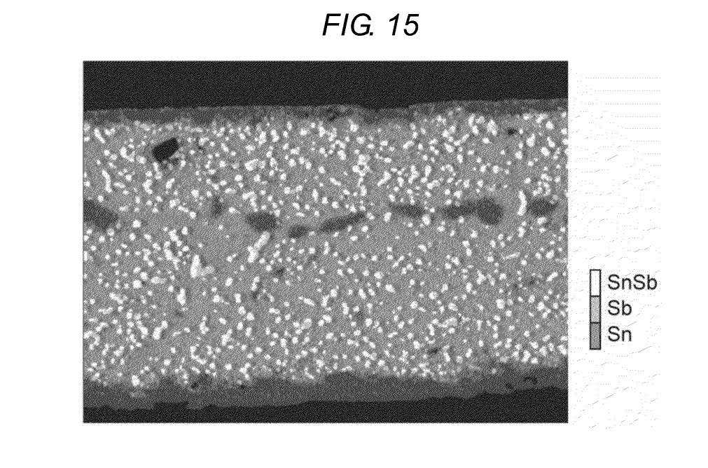

FIG. 12 is a graph illustrating a relationship between a crack length and the thickness of the junction portion 105 in which the SnSb material is used. FIG. 13 is a graph illustrating a relationship between a crack length and the thickness of the junction portion in which the SnSbCo material is used. In FIGS. 12 and 13, the horizontal axis represents the thickness (μm) of the junction portion 105, and the vertical axis represents the crack length (mm).

As illustrated in FIGS. 12 and 13, as the thickness of the junction portion 105 is increased, the crack length tends to be decreased. A change of the SnSb material of FIG. 12 in the crack length with respect to the thickness is greater than that of the SnSbCo material of FIG. 13. That is, the propagation of a crack may be suppressed by adding cobalt to the SnSb material.

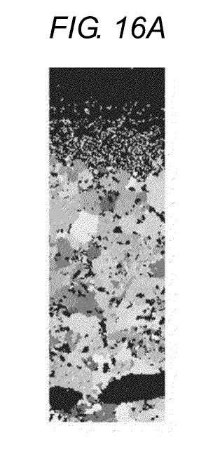

FIG. 14 is a cross-sectional SEM image illustrating the junction portion 105 in which the SnSb material is used.

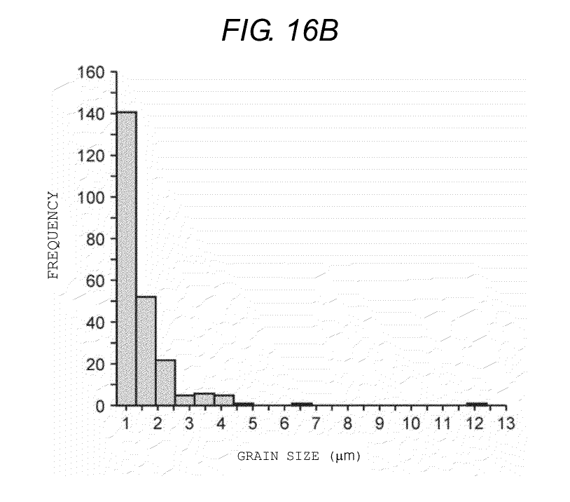

FIG. 15 is an X-ray image illustrating the junction portion 105 in which the SnSb material is used. FIG. 15 illustrates a distribution of SnSb, Sb, and Sn in the cross-section of FIG. 14. According to the analysis result of the cross-sectional view, a percentage (area ratio) of an area where antimony (Sb) is distributed alone (pure) is about 1.3%.

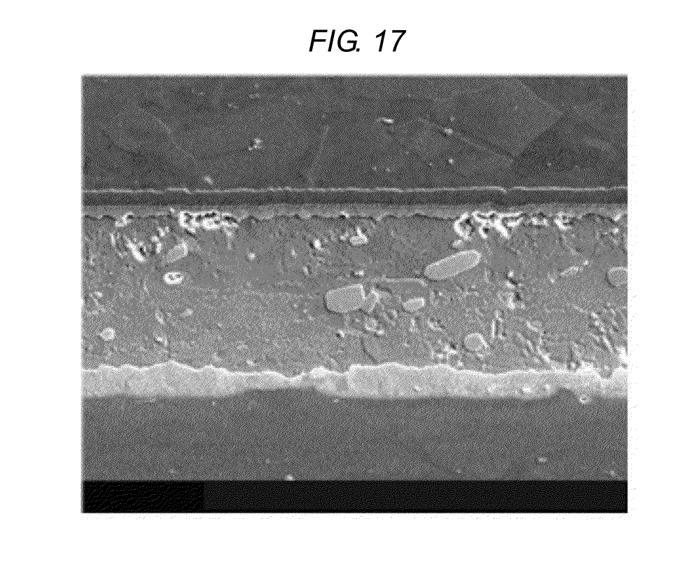

FIGS. 16A and 16B are diagrams illustrating a grain size distribution of the junction portion 105 in which the SnSb material is used.

FIG. 16A illustrates a crystal orientation distribution of the cross-section of FIG. 14 which is measured using an electron backscatter diffraction (EBSD) method. FIG. 16A illustrates a map of crystal grains of the cross-section of the junction portion 105.

FIG. 16B illustrates a grain size distribution corresponding to FIG. 16A. The horizontal axis represents the grain size, and the vertical axis represents the frequency. As illustrated in FIG. 16B, in the junction portion 105 in which the SnSb material is used, the frequency of crystal grains having a grain size of 1 μm is 140.

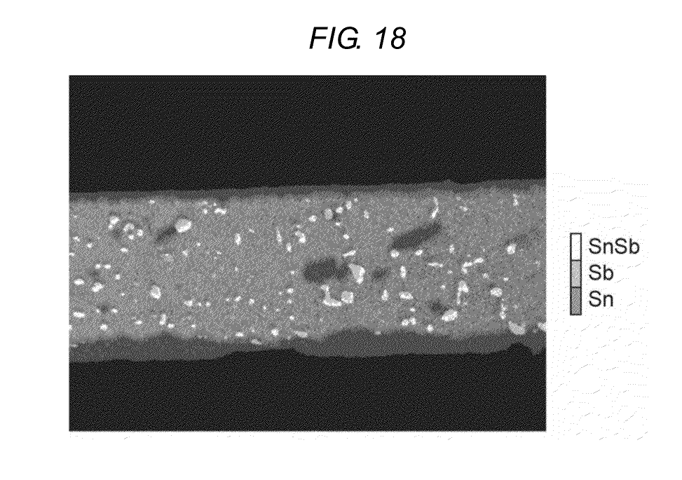

FIG. 17 is a cross-sectional SEM image illustrating the junction portion 105 in which the SnSbCo material is used.

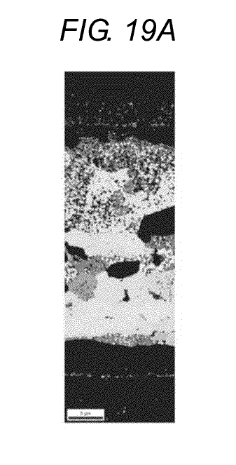

FIG. 18 illustrates a distribution of SnSb, Sb, and Sn in the cross-section of FIG. 17. According to the analysis result of the cross-sectional view, a ratio of an area where antimony (Sb) is present alone (pure) is about 0%. That is, substantially all the amount of antimony contained in the SnSbCo material is solid-solubilized in crystal.

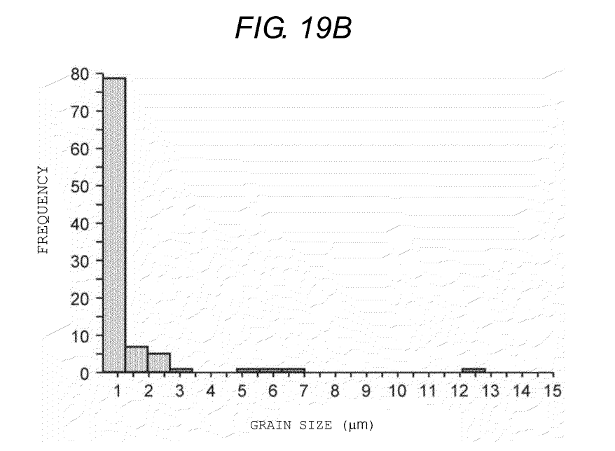

FIGS. 19A and 19B are diagrams illustrating a grain size distribution of the junction portion 105 in which the SnSbCo material is used.

FIG. 19A illustrates a crystal orientation distribution of the cross-section of FIG. 17 which is measured using an EBSD method and illustrates a map of crystal grains of the cross-section of the junction portion 105 in which the SnSbCo material is used. FIG. 19B illustrates a grain size distribution corresponding to FIG. 19A. The horizontal axis represents the grain size, and the vertical axis represents the frequency.

As clearly seen from a comparison between FIG. 19A and FIG. 16A, the typical grain size of the junction portion 105 in which the SnSbCo material is used is greater than that of the junction portion 105 in which the SnSb material is used. In addition, in the grain size distribution illustrated in FIG. 19B, the frequency of crystal grains having a grain size of 1 μm in the junction portion 105 in which the SnSbCo material is used is 90, which is less than the frequency of the junction portion 105 of FIG. 16B in which the SnSb material is used.

These results show that cobalt (Co) added to the SnSb material causes antimony (Sb) to be solid-solubilized in crystal and to increase a grain size thereof. Crystal grains having a large grain size tend to stop the propagation of a crack. That is, the SnSbCo material suppresses the propagation of a crack and also improves thermal fatigue resistance.

In addition, in the SnSbCo material, since the thickness dependency on the crack length is small, the thickness of the junction portion need not necessarily be closely controlled. For example, in the SnSb material, a technique of adding a material having a high melt point such as a nickel (Ni) to make the thickness uniform is used. However, in the SnSbCo material, use of this technique is not necessary, and the manufacturing cost may be reduced.

As such, by using the SnSbCo material for a junction portion of a semiconductor device, the solid-solubilizing of antimony may be promoted, and the grain size of crystal may be reduced. As a result, the thermal fatigue resistance of the junction portion may be improved, and the reliability of the semiconductor device may be improved. The junction portion according to the exemplary embodiment is not limited to the first junction portion 40 and the second junction portion 50 and may be used in a junction portion between other components included in the semiconductor device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a substrate joined to a base via a first junction material;
a semiconductor element joined to the substrate via a second junction material, wherein
at least one of the first junction material and the second junction material comprises tin, antimony, and cobalt.

2. The semiconductor device according to claim 1, wherein at least one of the first and second junction materials has a cobalt content that is equal to or greater than 0.05 wt % and equal to or less than 0.2 wt %.

3. The semiconductor device according to claim 2, wherein at least one of the first and second junction materials has an antimony content that is equal to or greater than 1 wt % and equal to or less than 10 wt %.

4. The semiconductor device according to claim 1, wherein at least one of the first and second junction materials has a cobalt-rich portion at a surface thereof.

5. The semiconductor device according to claim 1, further comprising:
a resin covering the base, the substrate, and the semiconductor element.

6. The semiconductor device according to claim 1, wherein the first junction material comprises tin, antimony, and cobalt.

7. The semiconductor device according to claim 1, wherein the second junction material comprises tin, antimony and cobalt.

8. The semiconductor device according to claim 1, wherein the second junction material has a melting point that is higher than a melting point of the first junction material.

9. The semiconductor device according to claim 1, wherein the first junction material comprises a plurality of solder sheets.

10. The semiconductor device according to claim 1, wherein the second junction material comprises a plurality of solder sheets.

11. The semiconductor device according to claim 1, wherein
the first junction material comprises cobalt with a weight percentage equal to or greater than 0.05 wt % and equal to or less than 0.2 wt %, antimony with a weight percentage equal to or greater than 1 wt % and equal to or less than 10 wt %, and tin,
the second junction material comprises cobalt with a weight percentage equal to or greater than 0.05 wt % and equal to or less than 0.2 wt %, antimony with a weight percentage equal to or greater than 1 wt % and equal to or less than 10 wt %, and tin, and
the second junction material has a melting point that is higher than a melting point of the first junction material.

12. A semiconductor device, comprising:
a semiconductor substrate including an electrode connected to a metal pattern via a junction material comprising tin, antimony, and cobalt.

13. The semiconductor device according to claim 12, wherein the junction material has a cobalt content of equal to or greater than 0.5 wt % and equal to or less than 0.2 wt %, an antimony content of equal to or greater than 1 wt % and equal to or less than 10 wt %, and a tin content substantially equal to 100 wt % minus the cobalt content and the antimony content.

14. The semiconductor device according to claim 12, wherein the metal pattern is disposed on a base plate that comprises alumina.

15. A method of manufacturing a semiconductor device, the method comprising:
placing a first junction material comprising tin, antimony, and cobalt between a base and a substrate; and
keeping temperatures of the base, the substrate, and the first junction material at a temperature higher than a melting point of the first junction material for at least one minute.

16. The method of claim 15, further comprising:
placing a second junction material comprising tin, antimony, and cobalt between the substrate and a semiconductor element; and
keeping temperatures of the substrate, the semiconductor element, and the second junction material at a temperature higher than a melting point of the second junction material for at least one minute.

17. The method of claim 16, wherein the second junction material has a melting point that is higher than a melting point of the first junction material.

18. The method of claim 16, wherein the second junction material has a cobalt content of equal to or greater than 0.5 wt % and equal to or less than 0.2 wt %, an antimony content of equal to or greater than 1 wt % and equal to or less than 10 wt %, and a tin content substantially equal to 100 wt % minus the cobalt content and the antimony content.

19. The method of claim 15, wherein the first junction material has a cobalt content of equal to or greater than 0.5 wt % and equal to or less than 0.2 wt %, an antimony content of equal to or greater than 1 wt % and equal to or less than 10 wt %, and a tin content substantially equal to 100 wt % minus the cobalt content and the antimony content.

20. The method of claim 15, wherein the first junction material is placed as a plurality of sheets between the base and the substrate.
